(19) United States
(12) Patent Application Publication
(10) Pub. No.: US 2024/0014678 A1
(43) Pub. Date: Jan. 11, 2024

(54) Battery Management System

(71) Applicant: Derek Simkowiak, Lynnwood, WA (US)

(72) Inventor: Derek Simkowiak, Lynnwood, WA (US)

(73) Assignee: Holding Zero, LLC, Albuquerque, NM (US)

(21) Appl. No.: 18/349,665

(22) Filed: Jul. 10, 2023

Related U.S. Application Data
(60) Provisional application No. 63/359,236, filed on Jul. 8, 2022.

(51) Int. Cl. H02J 7/00; H05K 1/18; H05K 3/40; H05K 3/30

(52) U.S. Cl. CPC H02J 7/00712; H02J 7/00304; H02J 7/0047; H02J 7/0013; H02J 7/0042; H05K 1/181; H05K 3/4007; H05K 3/4038; H05K 3/303; H02J 2207/30

(57) ABSTRACT

A battery management system comprises a printed circuit board having a current collector circuit and at least one independent battery cell management circuits. Each battery cell management circuit can sense and regulate the voltage and amperage of a single battery cell, such that each battery cell is independently managed for operation. Each battery cell management circuit includes a means for independently connecting a battery cell with said current collector circuit for electrical energy transfer. Said battery cell management circuits further include operational voltage and amperage values for a battery cell, which may vary over time, based on predetermined parameters. Each battery cell management circuit further includes operational limits, and a means for independently disconnecting a battery cell from said current collector circuit for electrical energy transfer. The battery cell management circuits can be operated concurrently for electrical energy transfer.

### CROSS-REFERENCE TO RELATED APPLICATIONS

This application claims the benefit of U.S. Provisional Patent Application Ser. No. 63/359,236 filed Jul. 8, 2022, titled “Battery Management System,” and the subject matter thereof is incorporated herein by reference thereto.

### TECHNICAL FIELD

The present invention is directed to a battery management system, and more particularly to structural and electrical aspects of a battery management system.

### BACKGROUND ART

The battery management systems of the present disclosure monitor and regulate battery “packs” comprised of at least one small, densely packed, cylindrical battery cells with cylinder radii generally less than about three inches, including, but not limited to, the cylindrical battery cell models 18650, 21700, and 26650 that have been standardized by the International Electrotechnical Commission (IEC) and the American National Standards Institute (ANSI).

An electrical circuit is a path in which electrons from a voltage or current source flow. When battery cells are connected electrically in parallel for concurrent electrical energy transfer, the individual connected battery cells are exposed to the shared voltage and amperage values through the parallel electrical connection. A single defective or failing battery cell connected in parallel may subject the rest of the battery cells to unsafe voltages, charge levels, and thermal conditions, which could lead to dangerous thermal runaway or toxic outgassing. Furthermore, such battery cells must all be manufactured with the same chemistry, operational voltage, and energy capacity, and for maintenance, a single such battery cell cannot be independently replaced with a newly manufactured battery cell without risking unsafe operating conditions. Thus, an improved battery management system is required which reduces or removes one or more of the issues mentioned. The present disclosure overcomes these limitations contained in the prior art.

None of the prior art fully addresses the problems resolved by the present invention. The present invention overcomes these limitations contained in the prior art.

Certain embodiments of the invention have other steps or elements in addition to or in place of those mentioned above. The steps or element will become apparent to those skilled in the art from a reading of the following detailed description when taken with reference to the accompanying figures, if any.

### BRIEF DESCRIPTION OF THE DRAWINGS

FIG. 1 illustrates an exploded view of the battery management system of the present disclosure.

FIG. 2 illustrates a top view of the battery management system of the present disclosure.

FIG. 3 illustrates a bottom view of the battery management system of the present disclosure.

FIG. 4 illustrates a simplified schematic of a battery cell management circuit of the present disclosure.

FIG. 5 illustrates a side view of a battery cell connector of the present disclosure.

FIG. 6 illustrates an example profile of regulated battery cell operational voltage and amperage over time of the present disclosure.

FIG. 7 illustrates a method of assembling the battery management system of the present disclosure.

### DETAILED DESCRIPTION OF THE INVENTION

The best mode for carrying out the invention will be described herein. The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. To avoid obscuring the present invention, some well-known system configurations, and process steps are not disclosed in detail. The figures illustrating embodiments of the system, if any, are semi-diagrammatic and not to scale and, particularly, some of the dimensions are for the clarity of presentation and are shown exaggerated in the drawing figures.

Alternate embodiments have been included throughout, and the order of such are not intended to have any other significance or provide limitations for the present invention.

For expository purposes, the term “horizontal” as used herein is defined as a plane parallel to the plane or surface of the present apparatus, regardless of its orientation. The term “vertical” refers to a direction perpendicular to the horizontal as just defined. Terms, such as “above”, “below”, “bottom”, “top”, “side”, “higher”, “lower”, “upper”, “over”, and “under”, are defined with respect to the horizontal plane, as shown in the figures, if any. The term “on” means that there is direct contact among elements.

The words “including”, “comprising”, “incorporating”, “consisting of”, “have”, and “is” are meant to be non-exclusive, meaning additional items, components or elements may be present. Joinder references such as “connected”, “connecting”, and “coupled” do not limit the position, orientation, or use of systems and/or methods, and do not necessarily infer that two elements are directly connected. All identifying numerical terms are for identification only, and do not refer to the order or preference of any element, embodiment, variation and/or modification.

The present disclosure provides a battery management system comprising a printed circuit board; wherein the printed circuit board comprises a current collector circuit; wherein the current collector circuit comprises one or more positive current collectors and one or more negative current collectors connected electrically in series or in parallel such that an electrical circuit is formed; wherein the printed circuit board further comprises a positive terminal and a negative terminal electrically connected to the positive side and negative side of said current collector circuit, respectively; wherein the printed circuit board further comprises at least one battery cell management circuits; wherein each of the at least one of battery cell management circuits comprises a battery cell connector, wherein the battery cell connector comprises a positive terminal and a negative terminal, such that a battery cell can be electrically connected for operation, wherein each of the at least one battery cell management circuits comprises: a means for sensing the voltage and amperage of a connected battery cell; predetermined operational limits for the voltage and amperage of a connected battery cell; predetermined parameters for the operational voltage and amperage values of a connected battery cell; a means to regulate the operational voltage and amperage values of a connected battery cell; and a means to connect a battery cell to said current collector circuit for electrical energy transfer, such that said current collector circuit can operate one or more battery cells concurrently with the voltage and amperage of each battery cell independently regulated; and wherein each of the at least one battery cell management circuits are electrically connected to the positive side and negative side of the current collector circuit.

The battery management system of the present disclosure further comprises: wherein the at least one battery cell management circuits further comprises a means for sensing the temperature of a battery cell, and predetermined operating limits for the temperature of a battery cell; wherein the at least one battery cell management circuits further comprises predetermined parameters for operational temperature values of a battery cell; wherein the printed circuit board further comprises a means to regulate the temperature of the one or more connected battery cells; wherein the at least one battery cell management circuits further comprises one or more data buses; wherein the one or more data buses comprises a two-wire data bus; wherein the one or more data buses updates any of the predetermined operational limits for the voltage and amperage of the battery cell and/or the predetermined parameters for operational voltage and amperage values of the battery cell with user-defined values; wherein the at least one battery cell management circuits further comprises one or more data buses, such that the one or more data buses updates any of the predetermined operational limits for the temperature of the battery cell and/or or the predetermined parameters for operational temperature values of a battery cell with user-defined values; wherein the printed circuit board further comprises a microcontroller, wherein the microcontroller comprises random access memory, one or more central processing units, and one or more input/output buses; wherein the microcontroller further comprises program memory, wherein the microcontroller can execute any of firmware and/or software; wherein the one or more microcontroller input/output buses is connected to each of the at least one battery cell management circuits; wherein the printed circuit board further comprises non-volatile data storage; wherein the printed circuit board further comprises a real-time clock; wherein the printed circuit board further comprises an accelerometer; wherein the printed circuit board further comprises an external data bus connector; and wherein each of the at least one battery cell management circuits further comprises one or more electrical fuses, wherein the connected battery cell retains overcurrent protection if the means to regulate the voltage and amperage of the connected battery cell exceeds the operating limits.

An alternate embodiment of the present disclosure provides a battery management system comprising a printed circuit board; wherein the printed circuit board comprises a current collector circuit; wherein the printed circuit board further comprises a positive terminal and a negative terminal electrically connected to a positive side and a negative side of the current collector circuit, respectively; wherein the printed circuit board further comprises at least one battery cell connector; wherein the at least one battery cell connector comprises a positive terminal and a negative terminal, such that a battery cell can be electrically connected for operation; wherein the printed circuit board further comprises a microcontroller that comprises random access memory, one or more central processing units, and one or more input/output buses; wherein the printed circuit board further comprises an external data bus connector; wherein the printed circuit board further comprises at least one battery cell management circuits; wherein the printed circuit board further comprises a means for sensing the voltage and amperage of the connected battery cell; wherein the printed circuit board further comprises predetermined operational limits for the voltage and amperage of the connected battery cell; wherein the printed circuit board further comprises predetermined parameters for the operational voltage and amperage values of the connected battery cell; wherein the printed circuit board further comprises a means to regulate the operational voltage and amperage values of the connected battery cell; and wherein the printed circuit board further comprises a means to connect the battery cell to the current collector circuit and to the one of the at least one battery cell management circuits for electrical energy transfer, such that the current collector circuit can operate one or more battery cells concurrently with the voltage and amperage of each battery cell independently regulated.

The present disclosure further provides a method of assembling a battery management system, the method comprising positioning electrical conductors on the top conducting layer of a printed circuit board such that a positive terminal, a negative terminal, and a current collector circuit are formed; positioning connecting circuit traces and component connecting pads on the bottom conducting layer of the printed circuit board, such that the connecting points for the surface-mount devices of at least one battery management circuits are formed; positioning at least one vias through a printed circuit board such that connecting points on the top conducting layer are coupled to connecting points on the bottom conducting layer and mount points for through-hole mounted discrete electrical components are formed; positioning discrete electrical components on a printed circuit board using surface-mount technology and through-hole mounting; and coupling discrete electrical components to a printed circuit board, such that at least one battery management circuits is formed, each independently connected to said current collector circuit.

The method of assembling a battery management system of the present disclosure further comprises: an external data bus connector on the printed circuit board; and at least one thermistors on the printed circuit board.

The present disclosure provides a battery management system comprised of a printed circuit board having a current collector circuit and at least one independent battery cell management circuits. Said current collector circuit includes one or more positive current collectors and one or more negative current collectors connected electrically in series or parallel such that an electrical circuit is formed. Each battery cell management circuit can sense and regulate the voltage and amperage of a single battery cell, such that each battery cell is independently managed for operation, including charging, discharging, standby mode, ship mode, inoperable mode, and other modes of operation.

Each battery cell management circuit includes a means for independently connecting a battery cell with said current collector circuit for electrical energy transfer. Said battery cell management circuits further include operational voltage and amperage values for a battery cell, which may vary over time, based on predetermined parameters. Each battery cell management circuit further includes operational limits, and a means for independently disconnecting a battery cell from said current collector circuit for electrical energy transfer.

The printed circuit board includes a positive terminal and a negative terminal electrically connected to the positive side and negative side of said current collector circuit, respectively, such that battery cells managed by the battery cell management circuits can be operated concurrently for electrical energy transfer using said terminals.

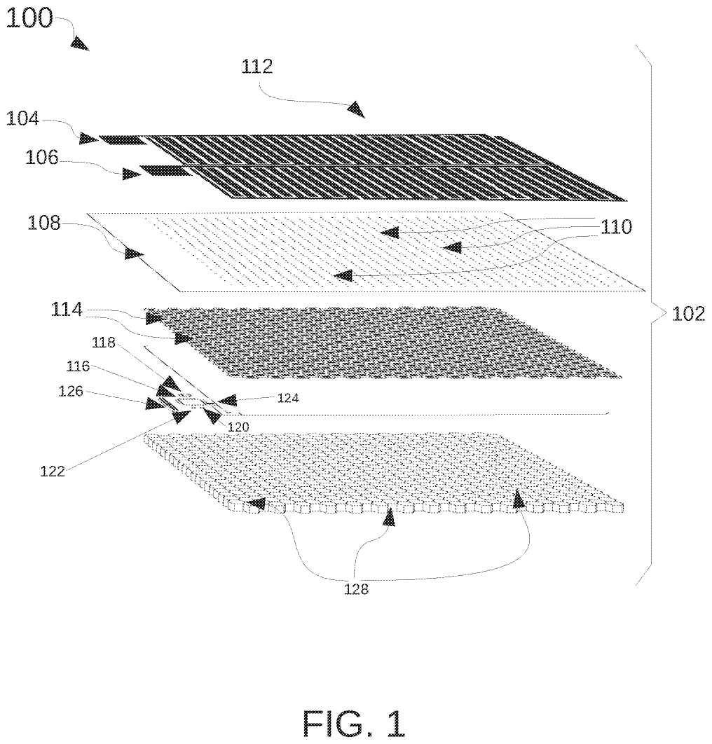

FIG. 1 illustrates an exploded view of the battery management system 100, according to certain embodiments of the invention. A printed circuit board 102 includes a current collector circuit 112 connected to a positive terminal 104 and a negative terminal 106 positioned on the top conducting layer of said printed circuit board 102. A non-conductive substrate layer 108 of the printed circuit board 102 electrically isolates the at least one battery cell management circuits 114 from said current collector circuit 112, except for the connections that connect each of said battery cell management circuits 114 to said current collector circuit 112, for individually regulated electrical energy transfer of a single battery cell. In the preferred embodiment, these connecting points are printed circuit board vias 110, but other embodiments are also possible.

Each of the at least one battery cell management circuits includes a battery cell connector 128 which can connect a single cylindrical battery cell to one of said battery cell management circuits 114.

In certain embodiments, the printed circuit board 102 may also include one or more additional electronic components, such as a microcontroller 116, non-volatile data storage 118, a real-time clock 120, an accelerometer 122, a microcontroller input/output bus 124, or an external data bus connector 126.

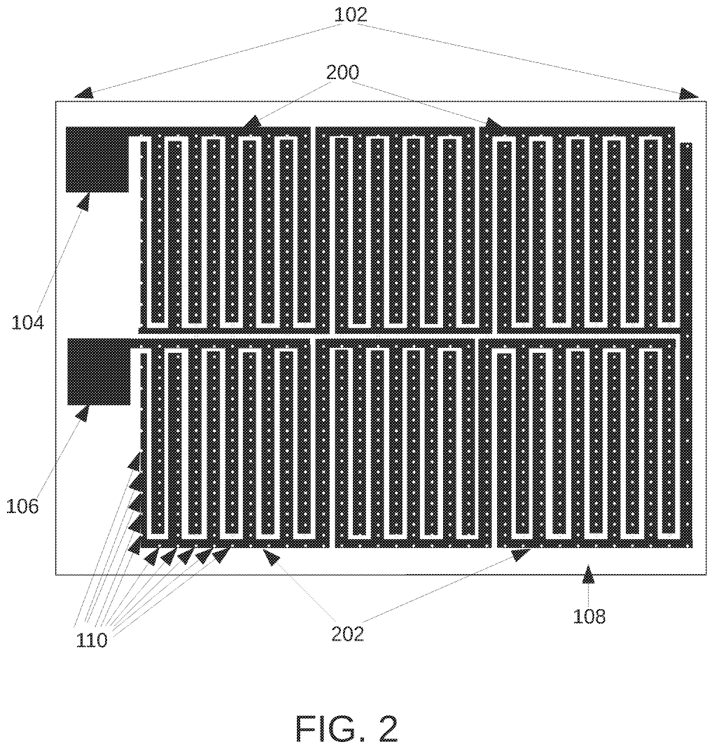

FIG. 2 illustrates a top view of the battery management system 100, according to certain embodiments of the invention. In certain embodiments, the top conducting layer of the printed circuit board 102 includes a positive terminal 104 and a negative terminal 106 electrically connected to a current collector circuit 112, including one or more positive current collectors 200 and one or more negative current collectors 202 connected electrically in series or in parallel such that an electrical circuit is formed. In certain embodiments, the current collector circuit 112 enables concurrent energy transfer from one or more battery cell management circuits 114 connected by vias 110, and a non-conductive substrate layer 108 electrically isolates the other circuits and electronic components of the printed circuit board 102 which must not be connected to said current collector circuit 112.

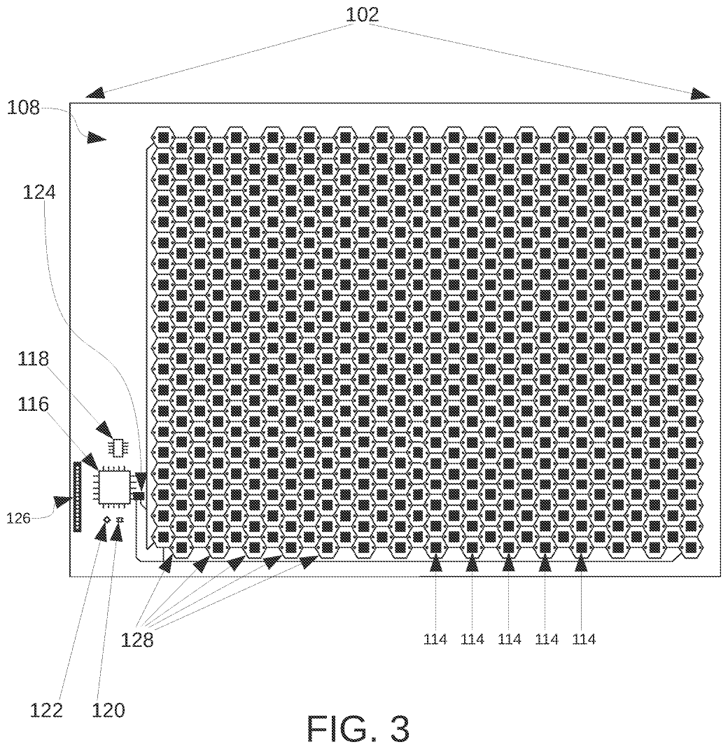

FIG. 3 illustrates a bottom view of the battery management system 100, according to certain embodiments of the invention. Electrically isolated from said current collector circuit 112 by a non-conductive substrate layer 108, each of the battery cell connectors 128 connects to a battery cell management circuit 114, such that cylindrical battery cells can be connected and the voltage and amperage of each battery cell can be independently regulated.

A microcontroller 116 may provide additional functionality to the battery management system 100. In some embodiments, said microcontroller 116 may include program memory, such that such that said microcontroller 116 can execute firmware, software, or firmware and software. In other embodiments, the CPU may need to be programmed after every reset using an external data bus connector 126.

In certain embodiments, one or more microcontroller input/output buses 124 is connected to each of the at least one battery cell management circuits 114 for digital signals, analog signals, or both digital signals and analog signals. Said microcontroller 116 may communicate with each of said battery cell management circuits 114 individually, for example, to read, process, cache, proxy, or save data from said battery cell management circuits 114, or to update predetermined parameters for the operational voltage and amperage values of a battery cell individually.

In certain embodiments, the battery management system 100 may include additional electronic components to provide additional functionality. non-volatile data storage 118 may be used to store data from the battery management system 100, or to store firmware or software instructions for a microcontroller 116. A real-time clock 120 may be used to supply date and time information to a microcontroller 116, which can be used for additional features such as timestamped data logging, and to vary the predetermined parameters for the operational voltage and amperage values of a battery cell based on calendar date and time of day. An accelerometer 122 may provide additional functionality such as vibration measurement or drop detection. In certain embodiments, one or more microcontroller input/output buses 124 is connected to each of said additional electronic components, with a microcontroller 116 connecting to an external data bus connector 126. In other embodiments, an external data bus connector 126 may be connected to one or more of said additional electronic components directly.

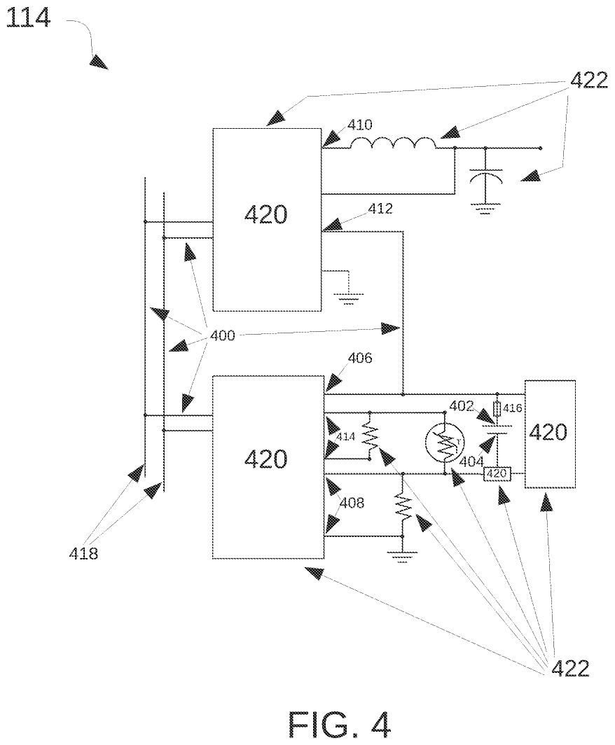

FIG. 4 illustrates a simplified schematic of a battery cell management circuit 114, according to certain embodiments of the invention. The positive terminal 402 and negative terminal 404 for connecting a cylindrical battery cell are shown. A means for sensing the voltage 406, a means for sensing the amperage 408, and a means for sensing the temperature 414 of a connected battery cell are illustrated as input pins on one or more integrated circuits 420 which are electronic components of the battery cell management circuit 114.

A means to regulate the operational voltage and amperage values of a connected battery cell 410, and a means to connect a battery cell to said current collector circuit 112 for electrical energy transfer 412, are illustrated as output pins on one or more integrated circuits 420 which are electronic components of the battery cell management circuit 114. A data bus of the battery cell management circuit 114 is illustrated as a two-wire data bus 418.

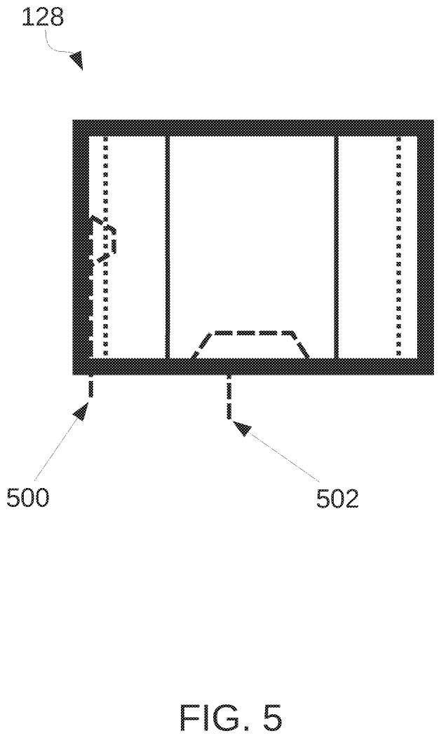

FIG. 5 illustrates a side view of a battery cell connector 128, according to certain embodiments of the invention. Each battery cell management circuit 114 includes a battery cell connector 128. The positive terminal 500 and negative terminal 502 of said battery cell connector 128 can connect to a cylindrical battery cell's cathode and anode, respectively.

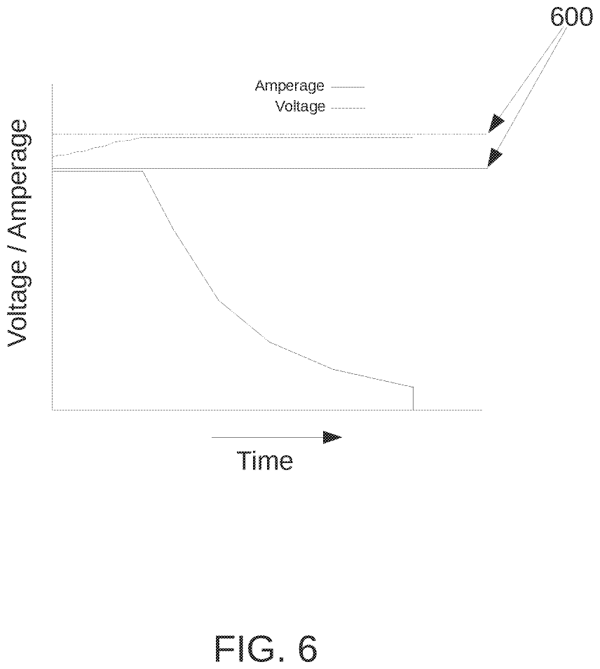

FIG. 6 illustrates an example profile of regulated battery cell operational voltage and amperage over time, according to certain embodiments of the invention. The operational limits 600 are illustrated as horizontal lines. Each battery cell management circuit 114 will prevent a connected battery cell from exceeding said operational limits 600, to prevent unsafe operation.

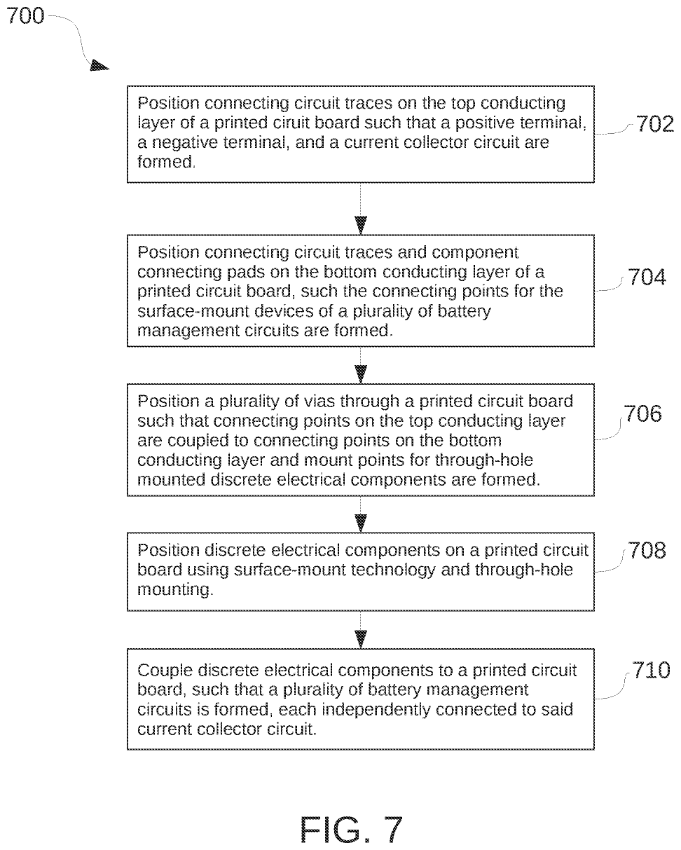

FIG. 7 illustrates a method 700 of assembling a battery management system 100, according to certain embodiments. According to method 700, at step 702 a positive terminal 104, a negative terminal 106, and a current collector circuit 112 are formed by positioning electrical conductors on the top conducting layer of a printed circuit board. These may be any suitable electrical conductor such as copper circuit traces, wires, or a bus bar, and may be positioned though a computer-assisted mechanism, as would be known to those of skill in the art, to use a datum on the printed circuit board 102 to achieve substantially accurate alignment.

According to method 700, at step 704 the connecting circuit traces 400 and component connecting pads are positioned on the bottom conducting layer of a printed circuit board 102, such that the connecting points for the surface-mount devices of the at least one battery cell management circuits 114 are formed. These may be made of any suitable electrical conductor such as copper, and may be positioned though a computer-assisted mechanism, as would be known to those of skill in the art, to use a datum on the printed circuit board 102 to achieve substantially accurate alignment.

According to method 700, at step 706 at least one of vias 110 are positioned through a printed circuit board such that connecting points on the top conducting layer are coupled to connecting points on the bottom conducting layer and connecting points for through-hole mounted discrete electrical components 422, as would be known to those of skill in the art, are formed. Said vias 110 may be positioned though a computer-assisted mechanism, as would be known to those of skill in the art, to use a datum on the printed circuit board 102 to achieve substantially accurate alignment.

According to method 700, at step 708, discrete electrical components 422 are positioned on a printed circuit board 102 using surface-mount technology and through-hole mounting, as would be known to those of skill in the art. Said discrete electrical components 422 include, but are not limited to, integrated circuits 420, resistors, capacitors, diodes, fuses 416, and transistors, and these may be positioned though a computer-assisted mechanism, such as a pick-and-place machine, as would be known to those of skill in the art, or by manual assembly.

According to method 700, at step 710 discrete electrical components 422 are coupled to a printed circuit board 102, such that at least one battery cell management circuits 114 is formed, each independently connected to said current collector circuit 112. The discrete electrical components 422 may be coupled using reflow soldering, as would be known to those of skill in the art, or they may be individually coupled using a soldering iron, as would be known to those of skill in the art.

The best mode for carrying out the invention has been described herein. The previous embodiments are described in sufficient detail to enable those skilled in the art to make and use the invention. It is to be understood that other embodiments would be evident based on the present disclosure, and that system, process, or mechanical changes may be made without departing from the scope of the present invention.

In the previous description, numerous specific details and examples are given to provide a thorough understanding of the invention. However, it will be apparent that the invention may be practiced without these specific details and specific examples. While the invention has been described in conjunction with a specific best mode, it is to be understood that many alternatives, modifications, and variations will be apparent to those skilled in the art in light of the foregoing description. Accordingly, it is intended to embrace all such alternatives, modifications, and variations that fall within the scope of the included claims. All matters previously set forth herein or shown in the accompanying figures are to be interpreted in an illustrative and non-limiting sense.

### LIST OF ELEMENTS SHOWN ON THE DRAWINGS

100 Battery management system
102 Printed circuit board
104 Positive terminal
106 Negative terminal
108 Non-conductive substrate layer
110 Vias
112 Current collector circuit
114 Battery cell management circuit
116 Microcontroller
118 Non-volatile data storage
120 Real-time clock
122 Accelerometer
124 Microcontroller input/output bus
126 External data bus connector
128 Battery cell connector
200 Positive current collector
202 Negative current collector
400 Connecting circuit traces
402 Positive terminal
404 Negative terminal
406 Means to sense voltage
408 Means to sense amperage
410 Means to regulate voltage and amperage
412 Means to connect a battery cell
414 Means to sense temperature
416 Fuse
418 Two-wire data bus
420 Integrated circuit
422 Discrete electrical components
500 Positive terminal
502 Negative terminal
600 Operational limits
700 Method
702 Step
704 Step
706 Step
708 Step
710 Step

What is claimed is:

1. A battery management system comprising:
a printed circuit board;
wherein the printed circuit board comprises a current collector circuit;
wherein the current collector circuit comprises one or more positive current collectors and one or more negative current collectors connected electrically in series or in parallel such that an electrical circuit is formed;
wherein the printed circuit board further comprises a positive terminal and a negative terminal electrically connected to the positive side and negative side of said current collector circuit, respectively;
wherein the printed circuit board further comprises at least one battery cell management circuits;
wherein each of the at least one of battery cell management circuits comprises a battery cell connector, wherein the battery cell connector comprises a positive terminal and a negative terminal, such that a battery cell can be electrically connected for operation, wherein each of the at least one battery cell management circuits comprises:
a means for sensing the voltage and amperage of a connected battery cell;
predetermined operational limits for the voltage and amperage of a connected battery cell;
predetermined parameters for the operational voltage and amperage values of a connected battery cell;
a means to regulate the operational voltage and amperage values of a connected battery cell; and
a means to connect a battery cell to said current collector circuit for electrical energy transfer, such that said current collector circuit can operate one or more battery cells concurrently with the voltage and amperage of each battery cell independently regulated; and
wherein each of the at least one battery cell management circuits are electrically connected to the positive side and negative side of the current collector circuit.

2. The battery management system of claim 1, wherein the at least one battery cell management circuits further comprises a means for sensing the temperature of a battery cell, and predetermined operating limits for the temperature of a battery cell.

3. The battery management system of claim 2, wherein the at least one battery cell management circuits further comprises predetermined parameters for operational temperature values of a battery cell.

4. The battery management system of claim 1, wherein the printed circuit board further comprises a means to regulate the temperature of the one or more connected battery cells.

5. The battery management system of claim 1, wherein the at least one battery cell management circuits further comprises one or more data buses.

6. The battery management system of claim 5, wherein the one or more data buses comprises a two-wire data bus.

7. The battery management system of claim 5, wherein the one or more data buses updates any of the predetermined operational limits for the voltage and amperage of the battery cell and/or the predetermined parameters for operational voltage and amperage values of the battery cell with user-defined values.

8. The battery management system of claim 3, wherein the at least one battery cell management circuits further comprises one or more data buses, such that the one or more data buses updates any of the predetermined operational limits for the temperature of the battery cell and/or or the predetermined parameters for operational temperature values of a battery cell with user-defined values.

9. The battery management system of claim 1, wherein the printed circuit board further comprises a microcontroller, wherein the microcontroller comprises random access memory, one or more central processing units, and one or more input/output buses.

10. The battery management system of claim 9, wherein the microcontroller further comprises program memory, wherein the microcontroller can execute any of firmware and/or software.

11. The battery management system of claim 9, wherein the one or more microcontroller input/output buses is connected to each of the at least one battery cell management circuits.

12. The battery management system of claim 1, wherein the printed circuit board further comprises non-volatile data storage.

13. The battery management system of claim 1, wherein the printed circuit board further comprises a real-time clock.

14. The battery management system of claim 1, wherein the printed circuit board further comprises an accelerometer.

15. The battery management system of claim 1, wherein the printed circuit board further comprises an external data bus connector.

16. The battery management system of claim 1, wherein each of the at least one battery cell management circuits further comprises one or more electrical fuses, wherein the connected battery cell retains overcurrent protection if the means to regulate the voltage and amperage of the connected battery cell exceeds the operating limits.

17. A battery management system comprising:
a printed circuit board;
wherein the printed circuit board comprises a current collector circuit;
wherein the printed circuit board further comprises a positive terminal and a negative terminal electrically connected to a positive side and a negative side of the current collector circuit, respectively;
wherein the printed circuit board further comprises at least one battery cell connector;
wherein the at least one battery cell connector comprises a positive terminal and a negative terminal, such that a battery cell can be electrically connected for operation;
wherein the printed circuit board further comprises a microcontroller that comprises random access memory, one or more central processing units, and one or more input/output buses;
wherein the printed circuit board further comprises an external data bus connector;
wherein the printed circuit board further comprises at least one battery cell management circuits;
wherein the printed circuit board further comprises a means for sensing the voltage and amperage of the connected battery cell;
wherein the printed circuit board further comprises predetermined operational limits for the voltage and amperage of the connected battery cell;
wherein the printed circuit board further comprises predetermined parameters for the operational voltage and amperage values of the connected battery cell;
wherein the printed circuit board further comprises a means to regulate the operational voltage and amperage values of the connected battery cell; and
wherein the printed circuit board further comprises a means to connect the battery cell to the current collector circuit and to the one of the at least one battery cell management circuits for electrical energy transfer, such that the current collector circuit can operate one or more battery cells concurrently with the voltage and amperage of each battery cell independently regulated.

18. A method of assembling a battery management system, the method comprising:
positioning electrical conductors on the top conducting layer of a printed circuit board such that a positive terminal, a negative terminal, and a current collector circuit are formed;
positioning connecting circuit traces and component connecting pads on the bottom conducting layer of the printed circuit board, such that the connecting points for the surface-mount devices of at least one battery management circuits are formed;
positioning at least one vias through a printed circuit board such that connecting points on the top conducting layer are coupled to connecting points on the bottom conducting layer and mount points for through-hole mounted discrete electrical components are formed;
positioning discrete electrical components on a printed circuit board using surface-mount technology and through-hole mounting; and
coupling discrete electrical components to a printed circuit board, such that at least one battery management circuits is formed, each independently connected to said current collector circuit.

19. The method of claim 18 further comprising an external data bus connector on the printed circuit board.

20. The method of claim 18 further comprising at least one thermistors on the printed circuit board.
